(19) United States
(12) Patent Application Publication
(10) Pub. No.: US 2007/0164426 A1
(43) Pub. Date: Jul. 19, 2007

(54) APPARATUS AND METHOD FOR INTEGRATED CIRCUIT COOLING DURING TESTING AND IMAGE BASED ANALYSIS

(75) Inventors: Patrick J. McGinnis, Poughkeepsie, NY (US); Darrell L. Miles, Wappingers Falls, NY (US); Richard W. Oldrey, Clintondale, NY (US); John D. Sylvestri, Poughkeepsie, NY (US); Manuel J. Villalobos, Wappingers Falls, NY (US)

Correspondence Address: CANTOR COLBURN LLP - IBM FISHKILL, 55 GRIFFIN ROAD SOUTH, BLOOMFIELD, CT, 06002, US

(73) Assignee: INTERNATIONAL BUSINESS MACHINES CORPORATION, Armonk, NY (US)

(21) Appl. No.: 11/306,982

(22) Filed: Jan. 18, 2006

(51) Int. Cl. H01L 23/34

(52) U.S. Cl. 257/714

(57) ABSTRACT

An apparatus for implementing integrated circuit cooling during testing and image-based analysis thereof includes a lid configured to define a cavity surrounding an integrated circuit die, the die mounted to a module substrate. One or more fluid passages are defined within the lid, wherein the passages facilitate the flow of a cooling liquid through said cavity and over the integrated circuit die, and a transparent window is formed within the lid so as to facilitate viewing of the integrated circuit die.

### BACKGROUND

The present invention relates generally to integrated circuit device testing and, more particularly, to an apparatus and method for implementing integrated circuit cooling during testing and image-based analysis thereof.

Fault isolation techniques are essential to the manufacture and development of large scale integrated circuit devices such as microprocessors. After the first production of a new integrated circuit design, there is generally a period of failure analysis as the design and manufacturing processes are adjusted to produce a successful product. The root cause failure analysis of some integrated circuits may be very time consuming, sometimes consuming days or even weeks to isolate a single fault on a single chip.

During image-based analyses of semiconductor chips such as, for example, Photo Emission Microscopy (PEM) and Optical Beam Induced Resistance Change (OBIRCH) techniques, modules with exposed integrated circuit chips are exercised by a tester while being observed by the particular imaging tool. During this type of image-based analysis, the configuration of imaging equipment typically prevents the use of conventional mechanisms for cooling the die during power up (e.g., heat sinks, heat spreaders). As such, alternative cooling approaches are typically employed during image-based testing and analysis.

For example, a die may simply be cooled through normal convection, wherein the surrounding ambient air cools the die. In addition, cooled air may be simply blown or channeled across the die. However, due to the ever increasing density of components formed within an integrated circuit die, such traditional cooling methods are rapidly becoming insufficient for providing adequate cooling during testing.

On the other hand, more exotic cooling methods may be used to, for example, direct a mist at the die, accompanied by elaborate methods for recovering and recirculating the liquid. Unfortunately, such solutions become excessively complex, expensive, and also incompatible with retrofitting of existing analytical tools. In view of the above, it would be desirable to provide a method and apparatus that allows for simple but adequate cooling of a semiconductor die for applications in which the die is subjected to an image-based analysis.

### SUMMARY

The above discussed drawbacks and deficiencies of the prior art are overcome or alleviated by an apparatus for implementing integrated circuit cooling during testing and image-based analysis thereof includes a lid configured to define a cavity surrounding an integrated circuit die, the die mounted to a module substrate. One or more fluid passages are defined within the lid, wherein the passages facilitate the flow of a cooling liquid through said cavity and over the integrated circuit die, and a transparent window is formed within the lid so as to facilitate viewing of the integrated circuit die.

In another embodiment, an apparatus for implementing integrated circuit cooling during testing and image-based analysis thereof includes a test socket mounted to a test circuit board and a module substrate mounted to the test socket, the module substrate having an integrated circuit die mounted thereon. A lid is mounted to the module substrate, the lid configured to define a cavity surrounding the integrated circuit die. One or more fluid passages are defined within the lid, wherein the passages facilitate the flow of a cooling liquid through the cavity and over the integrated circuit die. A transparent window is formed within the lid so as to facilitate viewing of the integrated circuit die.

In still another embodiment, a method for implementing integrated circuit cooling during testing and image-based analysis thereof includes defining a cavity to surround an integrated circuit die mounted to a module substrate, the cavity formed in a lid covering said module substrate. The flow of a cooling liquid is introduced through the cavity and over said integrated circuit die, the cooling liquid flowing through one or more fluid passages defined within the lid, wherein a transparent window formed within the lid facilitates viewing of the integrated circuit die during the flowing of the cooling liquid.

### BRIEF DESCRIPTION OF THE DRAWINGS

Referring to the exemplary drawings wherein like elements are numbered alike in the several Figures:

FIG. 1 is top view of an apparatus for implementing integrated circuit cooling during testing and image-based analysis, in accordance with an embodiment of the invention; and

FIG. 2 is a cross-sectional view of the apparatus for implementing integrated circuit cooling during testing and image-based analysis, taken along the lines 2-2 of FIG. 1.

### DETAILED DESCRIPTION

Disclosed herein is an apparatus and method for implementing integrated circuit cooling during testing and image-based analysis thereof. Briefly stated, the cooling is facilitated by the configuration and/or modification of a test or burn-in socket so as to form a liquid-tight cavity around the IC die. A cooling liquid is introduced into and through the cavity, thereby cooling the die. In addition, a transparent window is provided within the configured/modified test socket and positioned over the die to allow viewing of the die. The apparatus and methodology presented herein are easily implemented, without elaborate vapor reclamation methods, and can be retrofitted to existing systems. As compared to air, a cooling liquid is more efficient at removing the heat energy from the die and subsequently transporting it away from the image equipment.

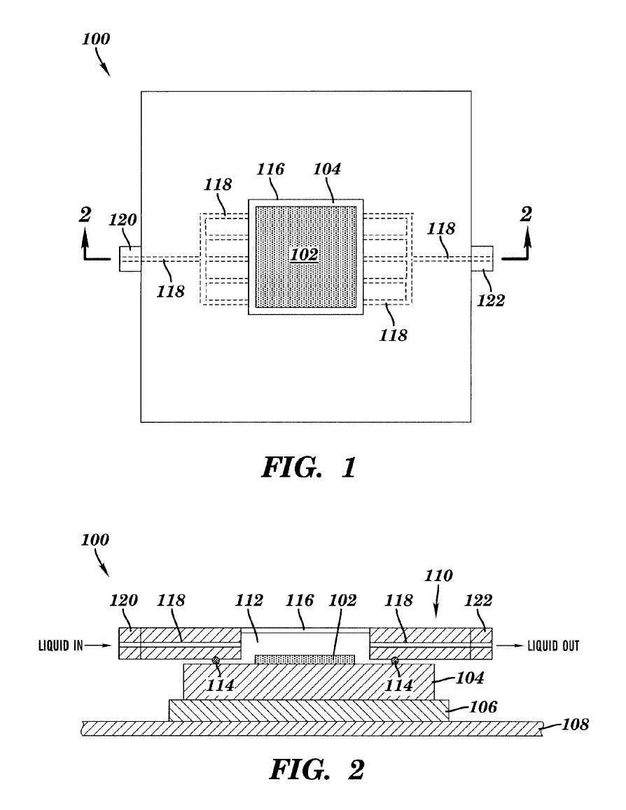

Referring generally to FIGS. 1 and 2, there is shown an apparatus 100 for implementing integrated circuit cooling during testing and image-based analysis, in accordance with an embodiment of the invention. As particularly shown in the cross-sectional view of FIG. 2, an integrated circuit die 102 under test is mounted to a module substrate 104. The manner in which the die 102 is packaged may be in accordance with any of the numerous component package designs known in the semiconductor arts including, but not limited to, ball grid array (BGA), land grid array (LGA), pin grid array (PGA), flip chip, quad flat pack (QFP), molded plastic, etc. The module substrate 104 is in turn placed within a test socket 106 that has the opposite side thereof connected to a testing circuit board 108. In an operating configuration, the testing circuit board 108 is connected to a control unit (not shown) for implementing the desired testing of the IC die 102.

In order to provide the desired cooling, the apparatus 100 features a lid 110 configured over the module substrate 104 and IC die 102. The lid 110 may be formed through a modification of a commercially available test or burn-in socket assembly, or it may be part of a separately configured component. In either case, the lid 110 (formed from a material such as stainless steel, for example) is configured so as to define an enclosed cavity 112 that surrounds the die 102, while also maintaining the ability to view the die 102 during analysis thereof. A sealing member 114 (such as an 0-ring, for example) is disposed between the lid 110 and the module substrate 104 or package so as to form a liquid tight seal therebetween. In addition, a transparent window 116 is positioned over the cavity 112 such that the die 102 may be viewed. The transparent window 116 can be formed from an optically clear material such as plexiglass, and sealed to the lid 110 using a suitable adhesive such as RTV (Room Temperature Vulcanizing) silicone available from General Electric. Other transparent materials and/or sealant materials may also be used, however.

As particularly illustrated in FIG. 1, the lid 110 includes a plurality of passages 118 formed therein so as to provide a fluid path through which a cooling liquid may be introduced into and circulated through the enclosed cavity 112. The cooling liquid is introduced into the apparatus 100 through coupling with an input port 120, and can be directed through a plurality of parallel passages 118 for even distribution of cooling liquid into the cavity 112 and over the IC die 102. The cooling liquid exits the cavity 112 through a corresponding series of parallel passages 118, and is removed from the apparatus through an output port 122. In an exemplary embodiment, a closed loop circulation system may be used to circulate and cool the cooling fluid passed through the cavity 112.

The cooling liquid may be selected from any suitable cooling substances known in the art such as, for example, deionized water or one of the Fluorinert™ perfluorinated electronic heat transfer liquids available from 3M Corporation. The Novec™ halon replacement fluids (also available from 3M) can also be used. Depending upon the amount of heat energy to be removed, the liquid may be introduced at room temperature or chilled by a recirculating chiller system.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. An apparatus for implementing integrated circuit cooling during testing and image-based analysis thereof, comprising:
a lid configured to define a cavity surrounding an integrated circuit die, said die mounted to a module substrate;
one or more fluid passages defined within said lid, wherein said passages facilitate the flow of a cooling liquid through said cavity and over said integrated circuit die; and
a transparent window formed within the lid so as to facilitate viewing of said integrated circuit die.

2. The apparatus of claim 1, further comprising a sealing member disposed between said lid and said module substrate so as to form a liquid tight seal therebetween.

3. The apparatus of claim 1, wherein said transparent window is disposed over said cavity.

4. The apparatus of claim 1, further comprising:
an input port for introducing said cooling liquid into said one or more fluid passages and said cavity; and
an output port for removing said cooling liquid from said one or more fluid passages and said cavity.

5. The apparatus of claim 4, wherein said one or more fluid passages further comprises a plurality of parallel passages configured for even distribution of said cooling liquid into said cavity and over said integrated circuit die.

6. The apparatus of claim 4, wherein said cooling liquid further comprises one or more of deionized water and a perfluorinated electronic heat transfer liquid.

7. The apparatus of claim 1, wherein said lid comprises a stainless steel material.

8. The apparatus of claim 1, wherein said module substrate comprises one or more of: a ball grid array (BGA) package, land grid array (LGA) package, pin grid array (PGA) package, a flip chip package, a quad flat pack (QFP) package, and a molded plastic package.

9. An apparatus for implementing integrated circuit cooling during testing and image-based analysis thereof, comprising:
a test socket mounted to a test circuit board;
a module substrate mounted to said test socket, said module substrate having an integrated circuit die mounted thereon;
a lid mounted to said module substrate, said lid configured to define a cavity surrounding said integrated circuit die;
one or more fluid passages defined within said lid, wherein said passages facilitate the flow of a cooling liquid through said cavity and over said integrated circuit die; and
a transparent window formed within the lid so as to facilitate viewing of said integrated circuit die.

10. The apparatus of claim 9, further comprising a sealing member disposed between said lid and said module substrate so as to form a liquid tight seal therebetween.

11. The apparatus of claim 9, wherein said transparent window is disposed over said cavity.

12. The apparatus of claim 9, further comprising:
an input port for introducing said cooling liquid into said one or more fluid passages and said cavity; and
an output port for removing said cooling liquid from said one or more fluid passages and said cavity.

13. The apparatus of claim 12, wherein said one or more fluid passages further comprises a plurality of parallel passages configured for even distribution of said cooling liquid into said cavity and over said integrated circuit die.

14. The apparatus of claim 12, wherein said cooling liquid further comprises one or more of deionized water and a perfluorinated electronic heat transfer liquid.

15. The apparatus of claim 9, wherein said lid comprises a stainless steel material.

16. The apparatus of claim 9, wherein said module substrate comprises one or more of: a ball grid array (BGA) package, land grid array (LGA) package, pin grid array (PGA) package, a flip chip package, a quad flat pack (QFP) package, and a molded plastic package.

17. A method for implementing integrated circuit cooling during testing and image-based analysis thereof, the method comprising:
defining a cavity to surround an integrated circuit die mounted to a module substrate, said cavity formed in a lid covering said module substrate;
introducing the flow of a cooling liquid through said cavity and over said integrated circuit die, said cooling liquid flowing through one or more fluid passages defined within said lid;
wherein a transparent window formed within the lid facilitates viewing of said integrated circuit die during the flowing of said cooling liquid.

18. The method of claim 17, further comprising: introducing said cooling liquid into said one or more fluid passages and said cavity through an input port; and removing said cooling liquid from said one or more fluid passages and said cavity through an output port.

19. The method of claim 18, wherein said one or more fluid passages further comprises a plurality of parallel passages configured for even distribution of said cooling liquid into said cavity and over said integrated circuit die.

20. The method of claim 18, wherein said cooling liquid further comprises one or more of deionized water and a perfluorinated electronic heat transfer liquid.
